(19) United States
(12) Patent Application Publication
(10) Pub. No.: US 2015/0375472 A1
(43) Pub. Date: Dec. 31, 2015

(54) COMPUTING DEVICE HAVING BIOMIMETIC MATERIAL

(71) Applicants: MARK SPRENGER, Folsom, CA (US); PAUL GWIN, Orangevale, CA (US); DAVID PIDWERBECKI, Hillsboro, OR (US); ALEKSANDER MAGI, Aloha, OR (US)

(72) Inventors: MARK SPRENGER, Folsom, CA (US); PAUL GWIN, Orangevale, CA (US); DAVID PIDWERBECKI, Hillsboro, OR (US); ALEKSANDER MAGI, Aloha, OR (US)

(21) Appl. No.: 14/318,343

(22) Filed: Jun. 27, 2014

(51) Int. Cl. B32B 3/30; B32B 7/08; H05K 5/02

(52) U.S. Cl. CPC B32B 3/30; H05K 5/02; B32B 7/08; B32B 2307/744; B32B 2457/00

(57) ABSTRACT

Techniques for forming a surface to attach a biomimetic material are described herein. The techniques include a method including forming a surface of a computing device, wherein the surface of the computing device comprises a feature to receive a biomimetic material. A biomimetic material is attached to the surface of the computing device via the feature of the surface.

### TECHNICAL FIELD

This disclosure relates generally to techniques for forming a surface to attach a biomimetic material. More specifically, the disclosure describes techniques for attaching the biomimetic material to the surface of a device.

### BACKGROUND

Some computing devices may include rubberized protrusions to increase stability when placed on a surface. Further, some computing devices may be connected to various cables and connectors that place pressure on the computing device resulting in a potential for rotational, lateral, or horizontal movement. In some scenarios, items, such as cables, connected to a given computing device may result in a shift in orientation of the computing device on a given surface. In yet other scenarios, a computing device may require human-device interaction which may result in undesired device movement, orientation, or tip due to lack of stabilization or poor weight distribution.

### BRIEF DESCRIPTION OF DRAWINGS

FIG. 1 is an illustration of a side view of a device having a biomimetic material to adhere to a surface.

FIG. 2 is an illustration of a perspective view of a surface of a device to be coupled to a biomimetic material.

FIG. 3 is an illustration of a perspective view of a surface of a device to be coupled to a double-sided biomimetic material.

FIG. 4 is an illustration of a perspective view of a surface of a device to be coupled to a biomimetic material via fastening features of the surface.

FIG. 5 is an illustration of a perspective view of a surface of a device to be coupled to a biomimetic material via fasteners to be received at holes defined in the surface.

FIG. 6 is an illustration of a perspective view of a pliable surface of a device coupled to a biomimetic material.

FIG. 7 is a diagram illustrating a perspective view of a semi-flexible substrate to be attached to a component.

FIG. 8 is a diagram illustrating a side view of a portion of the biomimetic material adhering to a non-uniform surface.

FIG. 9 is a block diagram illustrating a method of forming a surface to receive a biomimetic material.

### DETAILED DESCRIPTION

The subject matter disclosed herein relates to techniques for attaching a biomimetic material to a surface of a device. As discussed above, some devices may require a certain orientation for proper function. For example, a wireless communication device may be configured to require a given orientation to communicate with other devices. In this scenario, other components, such as cables, connected to the wireless communication device may present forces at the device, resulting in a tilt, or other change in orientation. As another example, a user of a given device may desire to place the device on a surface, such as in a car or on a desk, and expect the device to remain unmoved.

The techniques described herein include a biomimetic material configured to attach to a surface of the device via features of the surface. The biomimetic material may enable the device to retain a position, and may reduce movement of the device. The surface of the device includes one or more features for attaching the biomimetic material to the device. A biomimetic material, as referred to herein, is a material having a surface imitating a models, system, and/or elements of nature.

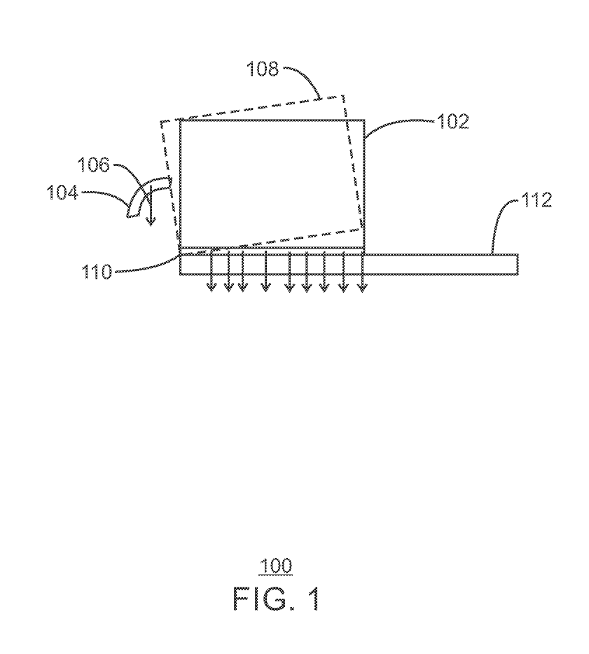

FIG. 1 is an illustration of a side view of a device having a biomimetic material to adhere to a surface. The example device 102 illustrated in FIG. 1 may be coupled to a cable 104. As indicated by the arrow 106, the cable 104 may exert a force potentially causing the device 102 to tilt and/or rotate as indicated by the dashed box 108. However, as discussed in more detail below, the device 102 may include a biomimetic material 110 disposed on a surface, such as the bottom surface (not shown) of the device 102. The biomimetic material 110 adheres to an external surface, such as the surface 112 illustrated in FIG. 1. The biomimetic material may be configured to maintain a surface force adhering to the external surface 112 with a lower profile than a standard suction cup, as well as for a longer period of time than a standard suction cup.

As discussed above, and in more detail below, the surface of the device 102 includes one or more features to attach the biomimetic material 110 to the surface of the device 102. The features may include a smooth surface such that the biomimetic material 110 adheres to the surface with more force required to detach the biomimetic material 110 from the device 102 than the external surface 112 to which the biomimetic material 110 is configured to attach. In some examples, smoothness may be defined by a surface having a stronger attachment to a biomimetic material than average household surfaces. Other types of features may include a covalent bond between the surface of the device 102 and the biomimetic material 110, mechanical mechanisms, other fastening mechanisms, and the like, as discussed in more detail below.

In one scenario, the device 102 is a computing device, such as a mobile computing device, a docking station, and the like. For example, the device 102 may be a wireless docking station having directional antennae. In this scenario, one or cables, such as the cable 104, may cause the wireless docking station to tilt, rotate, slide, etc., in such a way that the antennae would lose line of sight or connection performance.

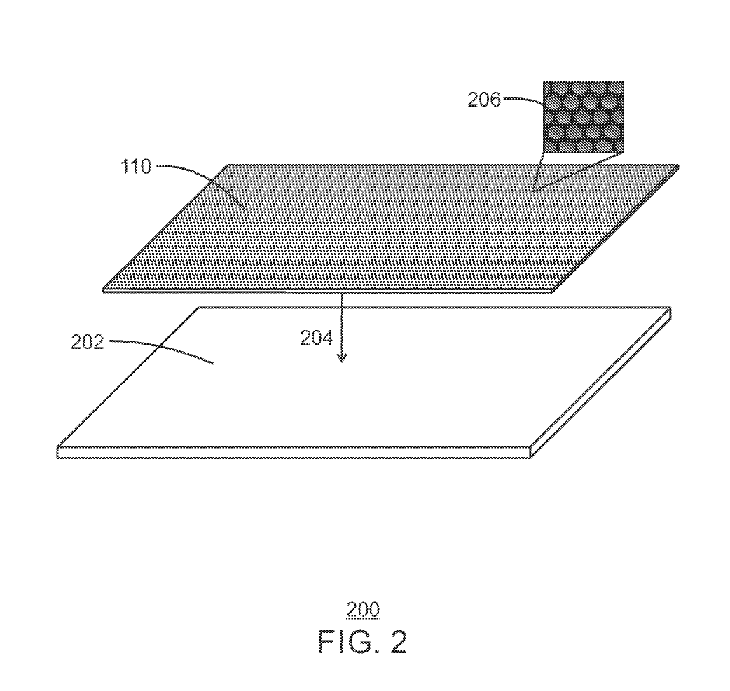

FIG. 2 is an illustration of a perspective view of a surface of a device to be coupled to a biomimetic material. A surface 202 may be a surface of a device, such as the bottom surface of the device 102 discussed above in regard to FIG. 1. As indicated at 204, the biomimetic material 110 may attach to the surface 102. An external side of the biomimetic material 110 may have multiple protrusions, mimicking the shape of a beetles' foot, as indicated in the scanning electron microscopic view in the box 206.

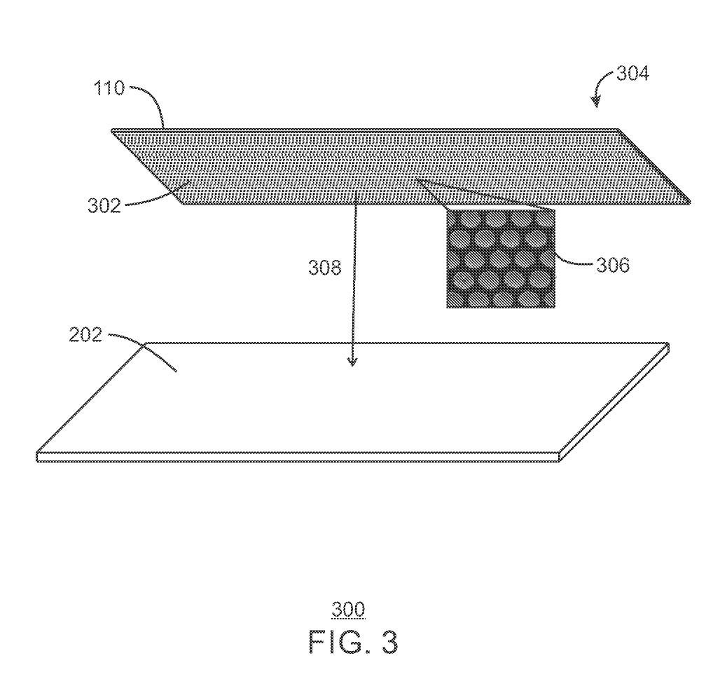

FIG. 3 is an illustration of a perspective view of a surface of a device to be coupled to a double-sided biomimetic material. In the example scenario of FIG. 3, the biomimetic material 110 may be double-sided wherein the beetles' feet protrusions are on both an internal side 302 of the biomimetic material, as well as on an external side of the biomimetic material 110, as indicated by the arrow 304. The internal side 302 of the biomimetic material 110 includes the protrusions of the biomimetic material as indicated by the scanning electron microscopic view illustrated at the box 306. The biomimetic material 110 may adhere to the surface 202 as indicated by the arrow 308. In this scenario, the surface 202 has been manufactured, or formed, such that the surface 202 is smoother than ordinary external surfaces the device will attach to, such as the surface 112 discussed above in regard to FIG. 1. The surface 202 may therefore exhibit a stronger Van der Waals force with the surface 202 of the device, as opposed to external surfaces.

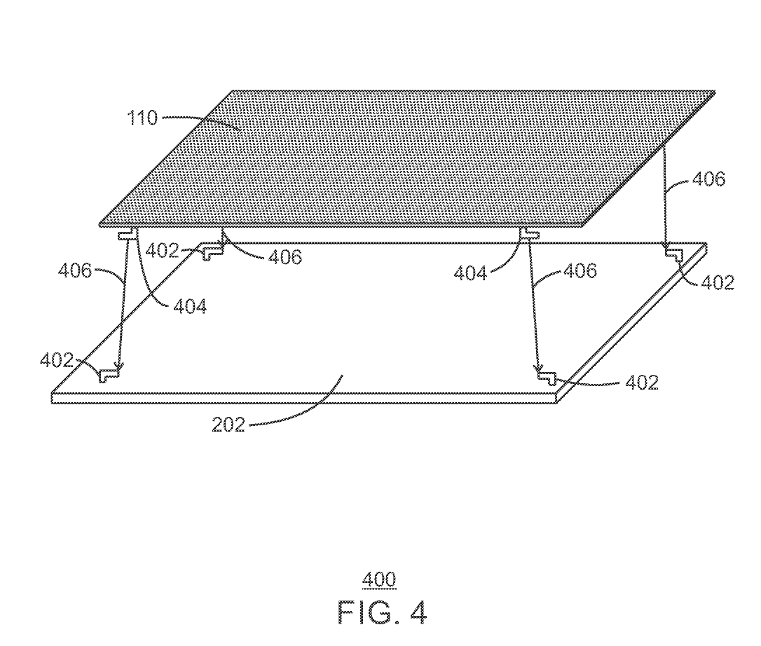

FIG. 4 is an illustration of a perspective view of a surface of a device to be coupled to a biomimetic material via fastening features of the surface. In the example scenario of FIG. 4, the surface 202 contains features 402. The features 402 may be latching mechanisms configured to receive latching mechanisms of the biomimetic material 110. The features 402 illustrated in FIG. 4 are only one example of a latching mechanism that may be used to attach the biomimetic material to the surface 202. The features 402 illustrated in the example scenario of FIG. 4 may be protrusions configured to receive protrusions 404 of the biomimetic material 110, recesses configured to receive protrusions 404 of the biomimetic material 110, as indicated by the arrows 406.

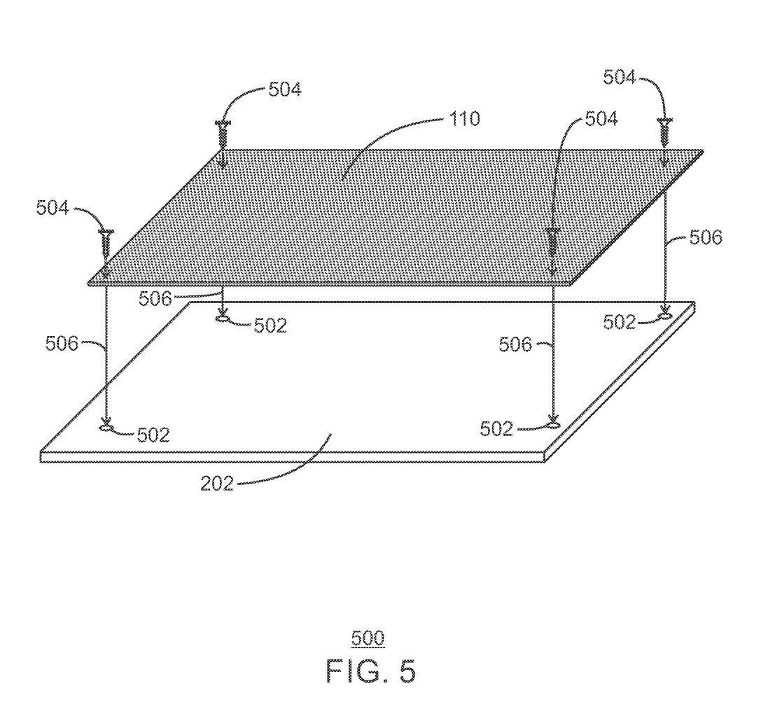

FIG. 5 an illustration of is a perspective view of a surface of a device to be coupled to a biomimetic material via fasteners to be received at holes defined in the surface. In the example scenario of FIG. 5, the surface 202 may include features 502. The features 502 may be holes defined by the surface 202 configured to receive fastening devices 504, as indicated by the arrows 506. The features 502 may enable the biomimetic material 110 to be received and attached to the surface 202.

In some scenarios, a combination of attachment mechanisms for attaching the biomimetic material 110 to the surface 202 may be used. For example, any combination of the biomimetic material 110 attachment mechanisms discussed above in regard to FIGS. 2-5 may be implemented.

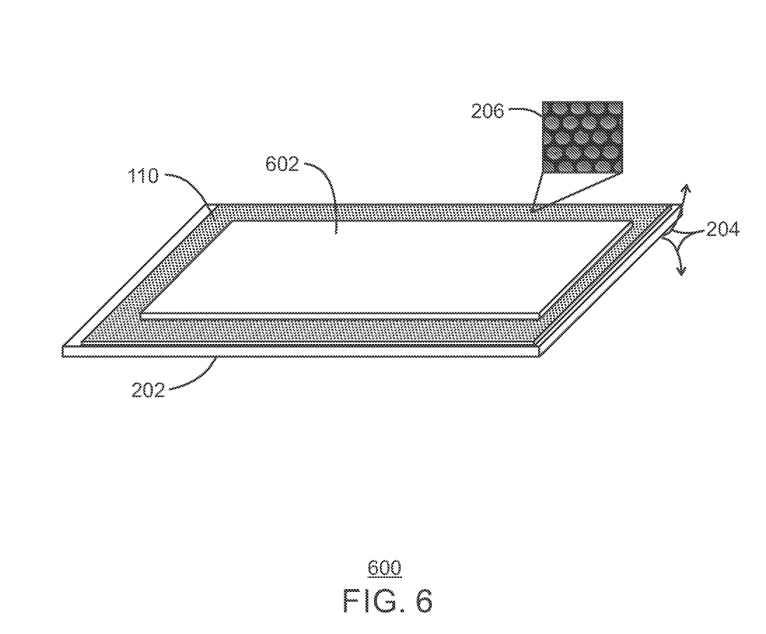

FIG. 6 is an illustration of a perspective view of a pliable surface of a device coupled to a biomimetic material. In the example scenario of FIG. 6, the surface 202 may be formed of a pliant material. For example, the surface 202 may be formed of a flexible plastic, rubber, or any other material that is pliable. In this example, any external surface, such as the external surface 602 coupled to the biomimetic material 110 may be coupled to the biomimetic material 110 and thereby attached to the surface 202. In order to detach the external surface 602 from the biomimetic material 110, the surface 202 may be bent, or flexed, such that the protrusions 206 are substantially released from a bond between the protrusions 202 of the biomimetic material 110. In this way, a device having a surface 202 with a biomimetic material 110 attached may be received, attached, and detached from an external surface 206.

FIG. 6 is an example illustration of a surface feature of a surface configured to adhere to an external surface via the biomimetic material 110. Other implementations are contemplated. For example, while the surface 202 in FIG. 6 is flexible to enable detachment of the biomimetic material 110 from an external surface, the flexibility may also enable attachment of the surface 202 via the biomimetic material to a non-uniform external surface.

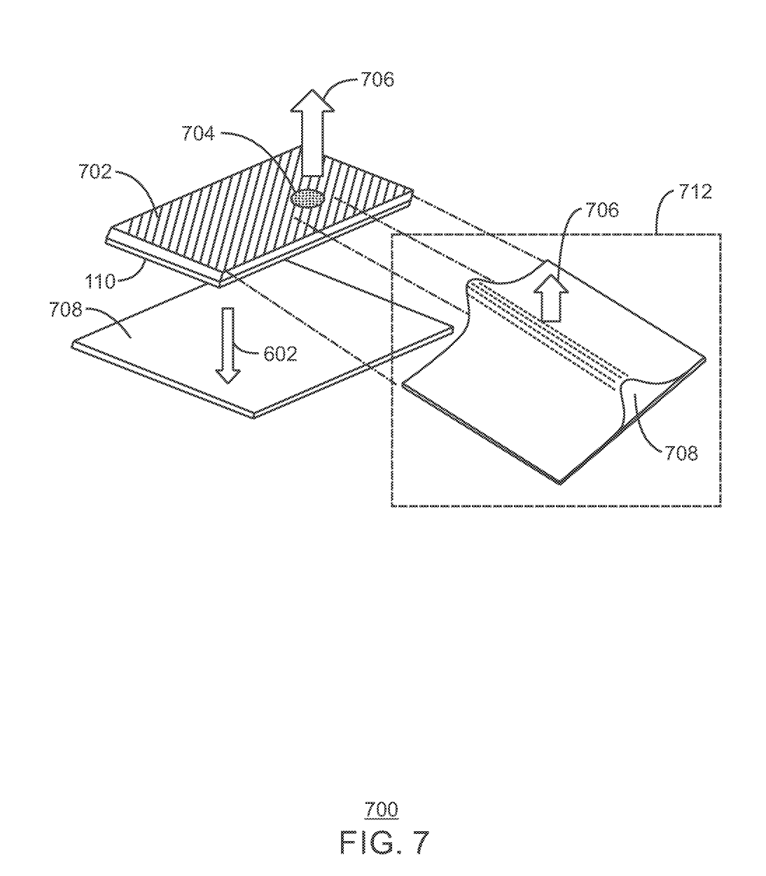

FIG. 7 is a diagram illustrating a perspective view of a semi-flexible substrate to be attached to a component. The semi-flexible substrate 702 may be structurally attached to the biomimetic material 110. The attachment between the semi-flexible substrate 702 may be via adhesive glue, a structural bond, such as the hydrogen and covalent bonds discussed above, or any other adhesion mechanism. The semi-flexible substrate 702 includes an adhesion area 704. The adhesion area 704 is configured to attach to a surface of the device, such as the surface 202 discussed above in reference to FIG. 2. The mechanism of attachment may include any of the attachment mechanisms discussed above in reference to FIGS. 2-5.

As illustrated in FIG. 7, the adhesion area 704 is smaller in dimension than the biomimetic material. As indicated at 706, a force may detach the biomimetic material 110 from an external surface 708. The force 706 may be in a direction opposite to a force in a direction indicated at 710 forming an adhesion of the biomimetic material 110 to the external surface 708. As indicated at the dashed box 712, the flexibility of the semi-flexible material 702 and the characteristics of the adhesion area 704, enables detachment of the biomimetic material 110 from the external surface 708. Specifically, because the adhesion area 704 is smaller in dimension than that the biomimetic material 110, the force 706 may cause the semi-flexible material to flex as indicated at 712, peeling the biomimetic material 110 from the external surface 708. Because peeling concentrates the load over a small surface area, this enables the device to be detached from the external surface with a lower force than the force required to attached the device to an external surface. This may enable force to be applied to the device in specific design directions to remove the device with less force while the intended adhesion of the device remains in the directions desired.

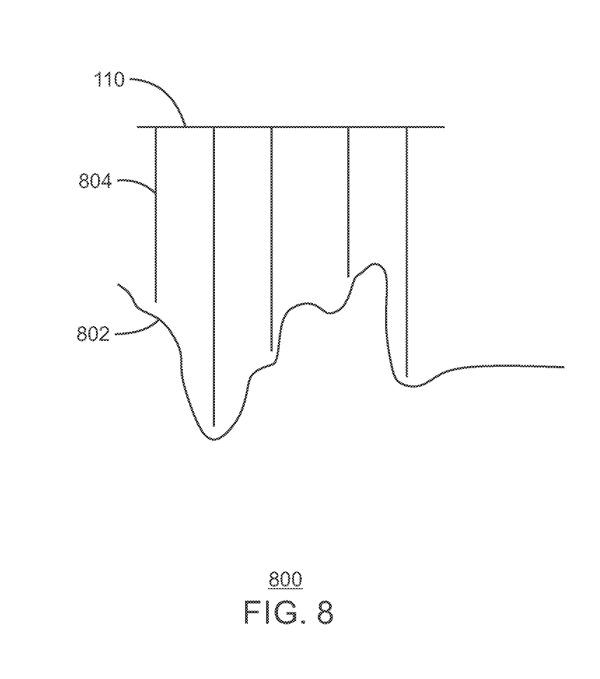

FIG. 8 is a diagram illustrating a side view of a portion of the biomimetic material adhering to a non-uniform surface. In some scenarios, an external surface 802 may not be uniform, as illustrated in FIG. 8. In this scenario, the biomimetic material 110 may include protrusions, such as the legs 804 having varying elastic modulus. Elastic modulus is a measure of stiffness of an elastic material. In FIG. 8, the legs 804 may be composed of an elastic material wherein the stiffness of the legs 804 enable the biomimetic material 110 to conform to the non-uniform external surface 802. Relative to other legs having a modulus, these legs may have a lower modules, and may be relatively shorter. The combination of low modulus and short legs enables a concentrated load to preserve the peeling mechanisms while allowing high surface contact of the feet to the external surface during an attachment process.

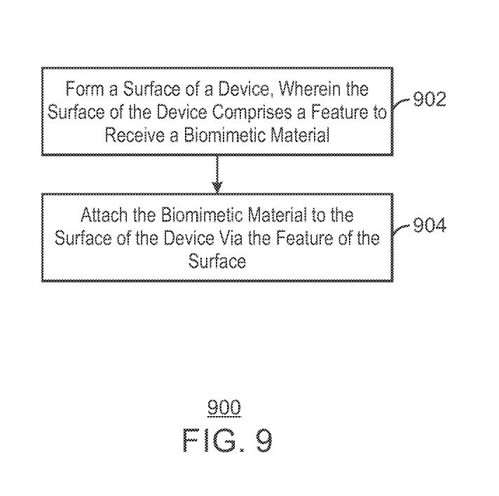

FIG. 9 is a block diagram illustrating a method of forming a surface to receive a biomimetic material. At block 902, a surface of a device is formed. The surface includes a feature to receive a biomimetic material. Example features may include a covalent bonding feature, a hydrogen bonding feature, a latching feature, a mechanical attachment feature, and the like. A biomimetic material is attached to the surface of the device via the feature of the surface, as indicated at block 904.

In general, the formed surface and attached biomimetic material may be used to attach a device to an external surface. As discussed above, some device may require a specific orientation that will be secured by the formed surface and the biomimetic material attached to surface.

Other scenarios may include attaching the biomimetic material of a desired surface of a device. For example, a user may desire to place a smartphone on a dashboard of a car. In this scenario, a bottom surface of the smartphone may have the biomimetic material attached via features of the bottom surface. Once the user places the biomimetic material on the dashboard of the car, significant movement may be reduced. As another example, a front edge of a 2-in-1 keyboard of a touchscreen computing device may be formed having features to attach the biomimetic material, and reduce tipping of the computing device when the biomimetic material adheres to an external surface such as a desk.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments.

Example 1 is a device having biomimetic material. The device may be a computing device, such as a mobile computing device. One or more surfaces of the device include a feature to receive the biomimetic material. The biomimetic material is attached to the one or more surfaces of the device via the feature of the surface.

Example 2 is a method of forming a surface to attach a biomimetic material. The method includes forming a surface of a device. The surface is to include a feature to receive a biomimetic material. The method includes attaching the biomimetic material to the surface of the device via the feature of the surface.

Example 3 is a system having biomimetic material. The system includes a device having a surface. The surface includes a feature to receive a biomimetic material. The system includes a biomimetic material attached to the surface of the device via the feature of the surface.

Example 4 includes a device having a biomimetic material. The device includes one or more surfaces, and the one or more surfaces includes a means to receive the biomimetic material. The biomimetic material is attached to the one or more surfaces of the device via the means of the surface.

Example 5 includes an apparatus for forming a surface to attach a biomimetic material. The apparatus includes a means for forming a surface of a device. The surface of the device includes a feature to receive the biomimetic material. The apparatus also includes a means for attaching the biomimetic material to the surface of the device via the feature of the surface.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. A computing device having biomimetic material, comprising:
one or more surfaces of the device, wherein the one or more surfaces of the device comprises a feature to receive a biomimetic material; and
a biomimetic material attached to the one or more surfaces of the device via the feature of the surface.

2. The computing device of claim 1, wherein a side of the biomimetic material opposite to the side attached to the one or more surfaces is configured to attach to an external surface.

3. The computing device of claim 1, wherein the biomimetic material comprises protrusions similar to protrusions of a beetle foot, and wherein the biomimetic protrusions adhere to surfaces via a Van Der Waals force.

4. The computing device of claim 1, wherein the feature of the one or more surfaces comprises:
a smoothness of the one or more surfaces wherein the biomimetic material attaches to the one or more surfaces with a greater resistance to detachment than an external surface attached to an opposite side of the biomimetic material;
a bond between the surface and the biomimetic material, comprising:
a covalent bond;
a hydrogen bond; or
any combination thereof;
a mechanical latching of the one or more surfaces to the biomimetic material; and
any combination of the features thereof.

5. The computing device of claim 1, a semi-flexible substrate having one or more adhesion areas to be attached to the one or more surfaces of the component, wherein the adhesion areas are smaller in dimension than the biomimetic material, and wherein the biomimetic material is structurally attached to the semi-flexible substrate on a side opposite to a side to be attached to the one or more surfaces of the component.

6. The computing device of claim 5, wherein the adhesion areas enable detachment of the biomimetic material to an external surface by flexing of the semi-flexible substrate as force is applied in a direction away from the external surface.

7. The computing device of claim 1, wherein the one or more surfaces of the component is a pliable surface such that movement of the one or more surfaces results in a detachment of the biomimetic material from an external surface.

8. The computing device of claim 1, wherein the one or more surfaces of the component is a conformable surface such that the biomimetic material may be conformably attached to a non-uniform external surface.

9. The computing device of claim 1, wherein the biomimetic material comprises protrusions to adhere to an external surface, wherein the protrusions comprise protrusions of varying elastic modulus.

10. The computing device of claim 1, wherein the computing device is a mobile computing device.

11. A method of forming a surface to attach a biomimetic material, comprising:
forming a surface of a device, wherein the surface of the device comprises a feature to receive a biomimetic material; and
attaching the biomimetic material to the surface of the device via the feature of the surface.

12. The method of claim 10, wherein a side of the biomimetic material opposite to the side attached to the formed surface is configured to attach to an external surface.

13. The method of claim 10, wherein the biomimetic material is formed similar to a beetle foot.

14. The method of claim 10, wherein the feature of the surface comprises a smoothness of the surface wherein the biomimetic material attaches to the surface with a greater resistance to detachment than an external surface attached to an opposite side of the biomimetic material.

15. The method of claim 10, wherein feature of the surface comprises a bond between the surface and the biomimetic material, comprising:
a covalent bond;
a hydrogen bond; or
any combination thereof.

16. The method of claim 10, wherein the feature of the surface comprises a mechanical latching of the surface to the biomimetic material.

17. The method of claim 10, wherein the surface of the component comprises a pliable surface such that movement of the surface results in a detachment of the biomimetic material from an external surface.

18. The method of claim 10, wherein a side of the biomimetic material opposite to the side attached to the formed surface is configured to attach to an external surface to reduce movement of the device.

19. A system having biomimetic material, comprising:
a device having a surface;
a feature of the surface to receive a biomimetic material; and
a biomimetic material attached to the surface of the device via the feature of the surface.

20. The system of claim 18, wherein a side of the biomimetic material opposite to the side attached to the surface is configured to attach to an external surface.

21. The system of claim 18, wherein the biomimetic material comprises protrusions similar to protrusions of a beetle foot, and wherein the biomimetic protrusions adhere to surfaces via a Van Der Waals force.

22. The system of claim 18, wherein the feature of the surface comprises a smoothness of the surface wherein the biomimetic material attaches to the surface with a greater resistance to detachment than an external surface attached to an opposite side of the biomimetic material.

23. The system of claim 18, wherein feature of the surface comprises a bond between the surface and the biomimetic material, comprising:
a covalent bond;
a hydrogen bond; or
any combination thereof.

24. The system of claim 18, wherein the feature of the surface comprises a mechanical latching of the surface to the biomimetic material.

25. The system of claim 18, wherein the surface of the component is a pliable surface such that movement of the surface results in a detachment of the biomimetic material from an external surface.

26. The system of claim 18, wherein a side of the biomimetic material opposite to the side attached to the formed surface is configured to attach to an external surface to reduce movement of the device.
